(19) United States
(12) Patent Application Publication
(10) Pub. No.: US 2006/0244130 A1
(43) Pub. Date: Nov. 2, 2006

(54) Multi-chip semiconductor package

(75) Inventor: Ping-Lin Yeh, Baoshan Shiang (TW)

Correspondence Address: BRUCE H. TROXELL, SUITE 1404, 5205 LEESBURG PIKE, FALLS CHURCH, VA, 22041, US

(73) Assignee: Holtek Semiconductor Inc.

(21) Appl. No.: 11/149,254

(22) Filed: Jun. 10, 2005

(30) Foreign Application Priority Data
Apr. 29, 2005 (TW) 94113829

(51) Int. Cl. H01L 23/495

(52) U.S. Cl. 257/723; 257/676; 257/724; 257/685

(57) ABSTRACT

The present invention discloses a multi-chip semiconductor package for packing a plurality of semiconductor chips of different functions in a signal package while allowing the plural chips to be made by different processes and thus to be assembled in a flexible manner, the multi-chip semiconductor package being characterized in that each chip packed in the package has at least two bonding pads being electrically connected to each other. Hence, the present invention can reduce the overall package size since the layout area required is decrease. Moreover, the design of connecting at least two bonding pads of each chip in the package enables the amount of leads needed in the package to remain the same while the amount of signals to be transmitted is increased, by which the size of the package can remain unchanged.

### 1. FIELD OF THE INVENTION

The present invention relates to a multi-chip semiconductor package, and more particularly, to a package structure for packing a plurality of semiconductor chips of different functions in a signal package while allowing the plural chips to be made by using different manufacturing processes.

### 2. BACKGROUND OF THE INVENTION

Up until now, most package structures of microcontroller chip or microprocessor chip do not have nonvolatile memory built therein, so that the electronic devices using the foregoing microcontroller/microprocessor chip will have no memory of any prior operations when the power supplies to the electronic devices are disconnected. To enable the aforesaid electronic devices to preserve their memory of prior operations, an additional nonvolatile memory connected externally to the foregoing package of microcontroller chip is required, wherein the nonvolatile memory can be an electrically erasable programmable read-only memory (EEPROM), a flash memory, a magnetoresistive random access memory (MRAM), etc. However, any conventional electronic devices using the additional nonvolatile memories for recording its operations will suffer not only from higher cost, but also from requiring larger layout area that is disadvantageous for making smaller, lighter and thinner electronic devices.

For those electronic device with multi-chip module, which packs a nonvolatile memory and a microprocessor chip is a single package, the nonvolatile memory and the microprocessor chip are generally being make by a same manufacturing process in order to facilitate the integration of overall manufacturing process. Nevertheless, although the process for manufacturing the aforesaid dual-chip package is simplified, the manufacturing flexibility is adversely affected that is consequently going to hurt the cost consideration. That is, if nonvolatile memories of different volume or characteristics are required, under the simplified manufacturing process, the design of the dual-chip package has to be change in order to meet with the different volatile memories.

Therefore, what is needed is a package structure capable of packing a plurality of semiconductor chips of different functions in a signal package while allowing the plural chips to be assembled in an flexible manner, which can reduce the overall package size and also reduce the overall manufacturing cost of the multi-chip module applying the package structure.

### SUMMARY OF THE INVENTION

In view of the disadvantages of prior art, the primary object of the present invention is to provide a multi-chip semiconductor package for packing a plurality of semiconductor chips of different functions in a signal package while allowing the plural chips to be assembled in a flexible manner, which can reduce the overall package size and also reduce the overall manufacturing cost of the multi-chip module applying the package structure.

To achieve the above object, the present invention provides a multi-chip semiconductor package, being encapsulated in an encapsulation body, comprising:
a die pad;
a first chip, mounted on the die pad, being equipped with a control function;
at least a second chip, mounted on the die pad at a position in the vicinity of that of the first chip, being equipped with a specific function;
a plurality of leads, arranged surrounding the die pad, for transmitting signals outputted from the first and the second chips out of the encapsulation body;
a plurality of bonding pads, arranged on the first and the second chips in respective, while at least two of the plural bonding pad arranged on the first chip are electrically connected to each other and at least two of the plural bonding pad arranged on the second chip are electrically connected to each other; and
a plurality of wires, electrically connecting the plural bonding pads, the plural leads and the die pad for enabling signal connections to be achieved among the first chip, the second chip and the plural leads;
wherein the amount of the lead is the same as that of a package packing only the first chip.

In a preferred embodiment of the invention, a first set of the plural wires is used for electrically connecting a first set of the bonding pads of the first chip to a first set of the bonding pads of the second chip, and a second set of the plural wires is used for electrically connecting a second set of the bonding pads of the first chip to a first set of the plural leads, and a third set of the plural wires is used for electrically connecting a third set of the bonding pads of the first chip to the die pad, and a fourth set of the plural wires is used for electrically connecting a second set of the bonding pads of the second chip to a second set of the plural leads, and a fifth set of the plural wires is used for electrically connecting a third set of the bonding pads of the second chip to the die pad, and a sixth set of the plural wires is used for electrically connecting the die pad to a third set of the plural leads.

Other aspects and advantages of the present invention will become apparent from the following detailed description, taken in conjunction with the accompanying drawings, illustrating by way of example the principles of the present invention.

### BRIEF DESCRIPTION OF THE DRAWINGS

FIG. 1 is a schematic view of a multi-chip semiconductor package of the present invention.

FIG. 2 is a schematic view of a multi-chip semiconductor package according to a first embodiment of the present invention.

FIG. 3 is a schematic view of a multi-chip semiconductor package according to a second embodiment of the present invention.

### DESCRIPTION OF THE PREFERRED EMBODIMENT

For your esteemed members of reviewing committee to further understand and recognize the fulfilled functions and structural characteristics of the invention, several preferable embodiments cooperating with detailed description are presented as the follows.

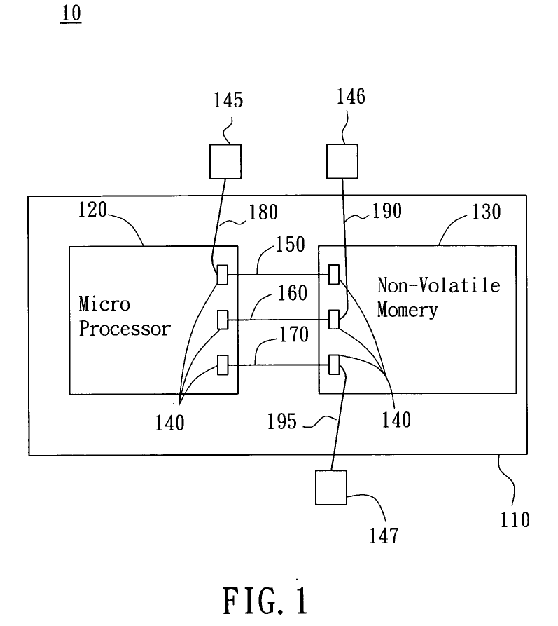

Please refer to FIG. 1, which is a schematic view of a multi-chip semiconductor package of the present invention. In FIG. 1, the multi-chip semiconductor package 10 is encapsulated in an encapsulation body, which is used primarily for encasing a die pad 110 and two chips, i.e. a microcontroller 120 and a nonvolatile memory 130, both disposed on the die pad 110. More particularly, the structure of the package 10 enables the making of the microcontroller 120 and the nonvolatile memory 130 to adopt different manufacturing processes.

As the making of the microcontroller 120 and the nonvolatile memory 130 adopt different manufacturing processes and when the multi-chip semiconductor package 10 is operating, the current and voltage received by the two chips 120, 130 are not quite the same in proportional and also the circuit density of the two chips 120, 130 are different since the architecture of the two chips 120, 130 are different, so that the manufacturing processes used for making the microcontroller 120 and the nonvolatile memory 130 can be adjusted accordingly.

Moreover, the amount of the leads required in the multi-chip semiconductor package 10 is no more than that of a package packing only the microcontroller 120. As seen in FIG. 1, the signal outputs of microcontroller 120 and the nonvolatile memory 130 are enabled by the plural wires 150, 160, 170, 180, 190, 195, which are used for electrically connecting the bonding pads 140 disposed on top of the microcontroller 120 and the nonvolatile memory 130 in respective, the leads 145, 146, 147 of the die pad 110, so that signals can be transmitted between the microcontroller 120 and the nonvolatile memory 130, and between the microcontroller 120 and the lead 145, and between the nonvolatile memory 130 and the leads 146, 147. To be more specific, the wire 150 is addressed as power line, the wire 160 is addressed as ground line, and the wire 170 is addressed as communication interface line, while the lead 145 is addressed as power lead, the lead 146 is addressed as ground lead, and the lead 147 is addressed as communication interface lead.

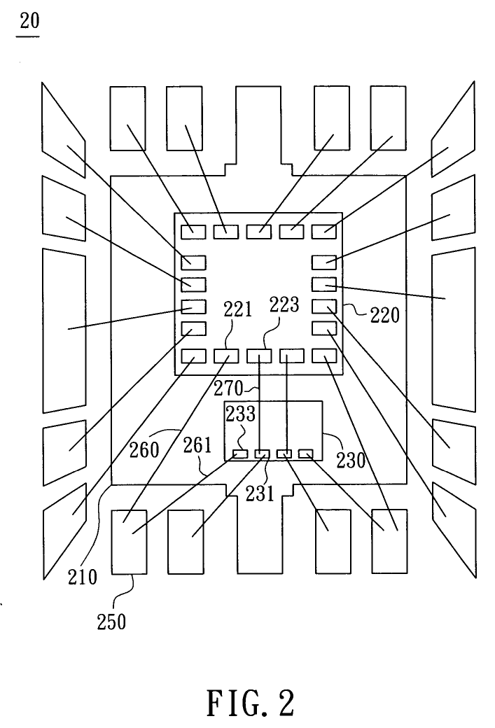

For enabling an encapsulation body to pack more than one chip without having to increase the amount of leads required for transmitting signals out of the encapsulation body, the path of the signal transmission between chips and between each chip and leads are specified. In a preferred embodiment of the invention as shown in FIG. 2, in order to avoid the need to have more leads in a multi-chip semiconductor package, each chip in the package will have at least two of the plural bonding pad arranged on same being electrically connected to each other.

Please refer to FIG. 2, which is a schematic view of a multi-chip semiconductor package according to a first embodiment of the present invention. The multi-chip semiconductor package 20 comprises a microcontroller 220 and a function chip 230, each having a plurality of bonding pads arranged on the top thereof, wherein the bonding pads 221, 223 disposed on top of the microcontroller 220 are electrically connected to each other while the bonding pads 231, 233 disposed on top of the function chip 230 are also electrically connected to each other so as to avoid the need to have more leads in the multi-chip semiconductor package 20. That is, the bonding pads 221, 223 can be treated as a same node in the circuit of the microcontroller 220 which is the same to the bonding pads 231, 233.

Since the bonding pads 221, 223 are treated and acting as a node while the bonding pads 231, 233 are also treated and acting as a node, there can be more than one transmission path for transmitting a signal from the bonding pad 221 of the microcontroller 220 to the lead 250. One of the paths is to transmit the signal from the bonding pad 221 to the lead 250 directly through the wire 160, and another path is to pass the signal from the bond pad 221 to the bonding pad 223 through the electrically connection between the two and then is being transmitted to the bond pad 231 through the wire 270 and further to be passed to the bonding pad 231, where the signal can be transmitted to the lead 250 by way of the wire 261.

By virtue of this, the leads required in the multi-chip semiconductor package 20 can remain the same even in the condition that there are more signals required to be outputted from the multi-chip semiconductor package 20 comprising the microcontroller 220 and a function chip 230, since the specific design of the connection between bonding pads of the microcontroller 220 and the function chip 230 enable the signal transmission paths to increase

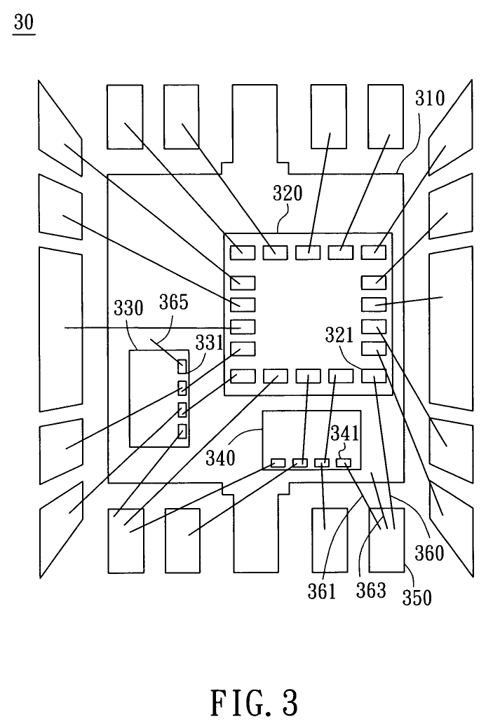

It is noted that the multi-chip semiconductor package of the invention is capable of incorporating more than one function chips. Please refer to FIG. 3, which is a schematic view of a multi-chip semiconductor package 30 packing a microcontroller 320, and two function chip 330, 340, each being disposed on a die pad 310.

As seen in FIG. 3, if a signal is to be transmitted from the bonding pad 321 of the microcontroller 320 to the bonding pad 341 of the function chip 330, it is first being transmitted from the bonding pad 321 to the lead 350 through the wire 360 where it is being transmitted to the bonding pad 341 by way of the wire 361, and if the signal is to be transmitted from the bonding pad 321 of the microcontroller 320 to the bonding pad 341 of the function chip 340, the signal is also first being transmitted from the bonding pad 321 to the lead 350 through the wire 360 where it is being transmitted to the die pad 310 to be passed to the bonding pad 331 by way of the wire 365.

From the above description, it is noted that the transmissions/receptions of the bonding pad 321 of the microcontroller 320, the bond pads 331, 341 of the function chips 330, 340 are enabled by a shared lead 350. Thus, since there are some leads in the multi-chip semiconductor package 30 are shared by the microcontroller 320 and the two function chips 330, 340, the amount of leads required in the multi-chip semiconductor package 30 can remain the same as that shown in FIG. 2, i.e. the total of eighteen leads.

The advantage of the invention is listed as following:
(a) By packing the microcontroller and nonvolatile memories in a same package without having to increase the amount of lead needed in the package, the applications of electronic device using the microcontroller can be extended.
(b) Instead of the nonvolatile memory, the microcontroller can be incorporated with other function chips e.g. liquid-crystal display chip, or other memory chips in a same package, so that the usage of the multi-chip semiconductor package is flexible and versatile.
(c) Since the amount of leads needed for the multi-chip semiconductor package is unchanged, the cost of the package in comparison can be reduce while reducing the overall manufacturing cost, and the same time that the space of multi-chip semiconductor package needed on of the printed circuit board is also without increasing so that the volume of the electronic products using the package can remain the same.
(d) The low-cost multi-chip semiconductor package can enable the electronic devices using the foregoing package to have memory of any prior operations when the power supplies to the electronic devices are disconnected, which enhance the intellectual performance of the microcontroller and further provide a much safer and convenient usage to consumers using the electronic devices.

To sum up, the present invention discloses a multi-chip semiconductor package for packing a plurality of semiconductor chips of different functions in a signal package while allowing the plural chips to be made by different processes and thus to be assembled in a flexible manner, the multi-chip semiconductor package being characterized in that each chip packed in the package has at least two bonding pads being electrically connected to each other. Hence, the present invention can reduce the overall package size since the layout area required is decrease. Moreover, the design of connecting at least two bonding pads of each chip in the package enables the amount of leads needed in the package to remain the same while the amount of signals to be transmitted is increased, by which the size of the package can remain unchanged.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments which do not depart from the spirit and scope of the invention.

What is claimed is:

1. A multi-chip semiconductor package, being encapsulated in an encapsulation body, comprising:
a die pad;
a first chip, mounted on the die pad, being equipped with a control function;
at least a second chip, mounted on the die pad at a position in the vicinity of that of the first chip, being equipped with a specific function;
a plurality of leads, arranged surrounding the die pad, for transmitting signals outputted from the first and the second chips out of the encapsulation body;
a plurality of bonding pads, arranged on the first and the second chips in respective, while at least two of the plural bonding pad arranged on the first chip are electrically connected to each other and at least two of the plural bonding pad arranged on the second chip are electrically connected to each other; and
a plurality of wires, electrically connecting the plural bonding pads, the plural leads and the die pad for enabling signal connections to be achieved among the first chip, the second chip, the plural leads and the die pad, while a first set of the plural wires being used for electrically connecting a first set of the bonding pads of the first chip to a first set of the bonding pads of the second chip, and a second set of the plural wires being used for electrically connecting a second set of the bonding pads of the first chip to a first set of the plural leads, and a third set of the plural wires being used for electrically connecting a third set of the bonding pads of the first chip to the die pad, and a fourth set of the plural wires being used for electrically connecting a second set of the bonding pads of the second chip to a second set of the plural leads, and a fifth set of the plural wires being used for electrically connecting a third set of the bonding pads of the second chip to the die pad, and a sixth set of the plural wires being used for electrically connecting the die pad to a third set of the plural leads;
wherein the amount of the lead is the same as that of a package packing only the first chip.

2. The multi-chip semiconductor package of claim 1, wherein the first chip is a microcontroller.

3. The multi-chip semiconductor package of claim 1, wherein the first chip is a microprocessor.

4. The multi-chip semiconductor package of claim 1, wherein the first chip is a controller chip.

5. The multi-chip semiconductor package of claim 1, wherein the second chip is a nonvolatile memory.

6. The multi-chip semiconductor package of claim 1, wherein the package comprises two second chips.

7. A multi-chip semiconductor package, being encapsulated in an encapsulation body, comprising:
a die pad;
a first chip, mounted on the die pad, being equipped with a control function;
at least a second chip, mounted on the die pad at a position in the vicinity of that of the first chip, being equipped with a specific function;
a plurality of leads, arranged surrounding the die pad, for transmitting signals outputted from the first and the second chips out of the encapsulation body;
a plurality of bonding pads, arranged on the first and the second chips in respective, while at least two of the plural bonding pad arranged on the first chip are electrically connected to each other and at least two of the plural bonding pad arranged on the second chip are electrically connected to each other; and
a plurality of wires, electrically connecting the plural bonding pads, the plural leads and the die pad for enabling signal connections to be achieved among the first chip, the second chip, the plural leads and the die pad;
wherein the amount of the lead is the same as that of a package packing only the first chip.

8. The multi-chip semiconductor package of claim 7, wherein a first set of the plural wires is used for electrically connecting a first set of the bonding pads of the first chip to a first set of the bonding pads of the second chip.

9. The multi-chip semiconductor package of claim 7, wherein a second set of the plural wires is used for electrically connecting a second set of the bonding pads of the first chip to a first set of the plural leads.

10. The multi-chip semiconductor package of claim 7, wherein a third set of the plural wires is used for electrically connecting a third set of the bonding pads of the first chip to the die pad.

11. The multi-chip semiconductor package of claim 7, wherein a fourth set of the plural wires is used for electrically connecting a second set of the bonding pads of the second chip to a second set of the plural leads.

12. The multi-chip semiconductor package of claim 7, wherein a fifth set of the plural wires is used for electrically connecting a third set of the bonding pads of the second chip to the die pad.

13. The multi-chip semiconductor package of claim 7, wherein a sixth set of the plural wires is used for electrically connecting the die pad to a third set of the plural leads.

14. The multi-chip semiconductor package of claim 7, wherein the first chip is a microcontroller.

15. The multi-chip semiconductor package of claim 7, wherein the first chip is a microprocessor.

16. The multi-chip semiconductor package of claim 7, wherein the first chip is a controller chip.

17. The multi-chip semiconductor package of claim 7, wherein the second chip is a nonvolatile memory.

18. The multi-chip semiconductor package of claim 7, wherein the package comprises two second chips.
